(19) United States
(12) Patent Application Publication
(10) Pub. No.: US 2024/0356548 A1
(43) Pub. Date: Oct. 24, 2024

(54) Output Driver Circuits And Methods With Hot-Socket Protection

(71) Applicant: Altera Corporation, San Jose, CA (US)

(72) Inventors: Pai Ho Bong, Bayan Lepas (MY); Sean Woei Voon, Bukit Mertajam (MY); Shyue Loong Lim, Lunas (MY); Chong Xin Tan, Sitiawan (MY)

(73) Assignee: Altera Corporation, San Jose, CA (US)

(21) Appl. No.: 18/763,451

(22) Filed: Jul. 3, 2024

(51) Int. Cl. H03K 19/003; H03K 19/0185

(52) U.S. Cl. CPC H03K 19/00315; H03K 19/018528; H03K 19/018585

(57) ABSTRACT

An integrated circuit includes an output driver circuit having first and second transistors coupled to an external pad of the integrated circuit and first and second multiplexer circuits. The first multiplexer circuit is configurable to cause the first transistor to be controlled by a first voltage during a data output mode of operation and to couple a first control input of the first transistor to the external pad during a hot-socket protection mode of operation. The second multiplexer circuit is configurable to cause the second transistor to be controlled by a second voltage during the data output mode of operation and to couple a second control input of the second transistor to the external pad during the hot-socket protection mode of operation.

### TECHNICAL FIELD

The present disclosure relates to electronic integrated circuits and systems, and more particularly, to output driver circuits and methods having hot-socket protection.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the configurable integrated circuit to perform the functions of the custom circuit design.

### BRIEF DESCRIPTION OF DRAWINGS

FIG. 1 is a diagram that depicts an example of an output driver circuit in an integrated circuit (IC) that can support a high voltage at an external pad of the IC during a hot-socket condition of the IC.

FIG. 2 is a diagram that illustrates an example of a clamp protection circuit in an IC that generates a bias voltage in response to the voltage at an external pad and a supply voltage.

FIG. 3 is a diagram that illustrates an example of a power detector circuit.

FIG. 4 depicts timing diagrams that illustrate examples of voltage waveforms in the output driver circuit of FIG. 1, the clamp protection circuit of FIG. 2, and the power detector circuit of FIG. 3 during a data output mode of operation and during a hot-socket protection mode of operation.

FIG. 5 is a diagram that illustrates an example of a configurable logic integrated circuit (IC) that can include circuitry disclosed herein with respect to any of FIGS. 1-3.

FIG. 6A illustrates a block diagram of a system that can be used to implement a circuit design to be programmed onto a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

A hot-socket condition of an integrated circuit (IC) occurs when the IC is un-powered and an external device drives a voltage to at least one input or output pad of the IC through interconnects in a circuit board or within an IC package. Thus, during a hot-socket condition, an input or output pad of an IC receives a signal before the IC is powered up. Contention may occur when an IC is hot-socketed. When an IC is hot-socketed, logic levels may appear in the IC before the power supply can provide current to the supply voltage and ground networks of the IC. An integrated circuit (IC) may experience significant voltages (e.g., 2 volts or greater) at one or more of its input/output pads when the supply voltage of the IC is still at or near zero volts. The voltage appearing at an input/output pad during a hot-socket condition may cause an electrical over stress (EOS).

A field programmable gate array (FPGA) is a type of configurable integrated circuit (IC). Some legacy FPGA ICs have high voltage input/output (HVIO) driver circuits that include single stack thick gate field-effect transistors that natively support a terminal (e.g., pad) voltage up to 3 volts without experiencing breakdown.

Many advanced semiconductor process nodes that have reduced transistor dimensions do not have native thick gate field-effect transistors that can support up to 3 volts without breakdown. Instead, these advanced semiconductor process nodes have field-effect transistors that can only support up to 1.8 volts before breakdown occurs. Therefore, there is a need to stack together multiple field-effect transistors (FETs) that individually support up to 1.8 volts in order to support a high voltage up to 3.3 volts at an input or output pad during a hot-socket condition.

According to some examples disclosed herein, an output driver circuit is provided in an IC that can support a high voltage at an external pad of the IC during a hot-socket condition of the IC. The output driver circuit includes two stacked p-channel field-effect transistors (FETs) coupled to the external pad and two stacked n-channel FETs coupled to the external pad. A clamp protection circuit is provided that generates a bias voltage from the greater of the voltage at the external pad or a supply voltage. The bias voltage generated by the clamp protection circuit is provided to the body terminals of the stacked p-channel FETs and other p-channel FETs in the output driver circuit. The bias voltage prevents the body diodes of the p-channel FETs from becoming forward biased during hot-socket conditions. The output driver circuit also includes multiplexer circuits that cause one of the p-channel FETs and one of the n-channel FETs to be controlled by input voltages during a data output mode of operation. The multiplexer circuits couple the control input of the one of the p-channel FETs and the control input of the one of the n-channel FETs to the external pad during a hot-socket protection mode of operation. The multiplexer circuits are controlled by a power detector circuit.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices or circuits that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

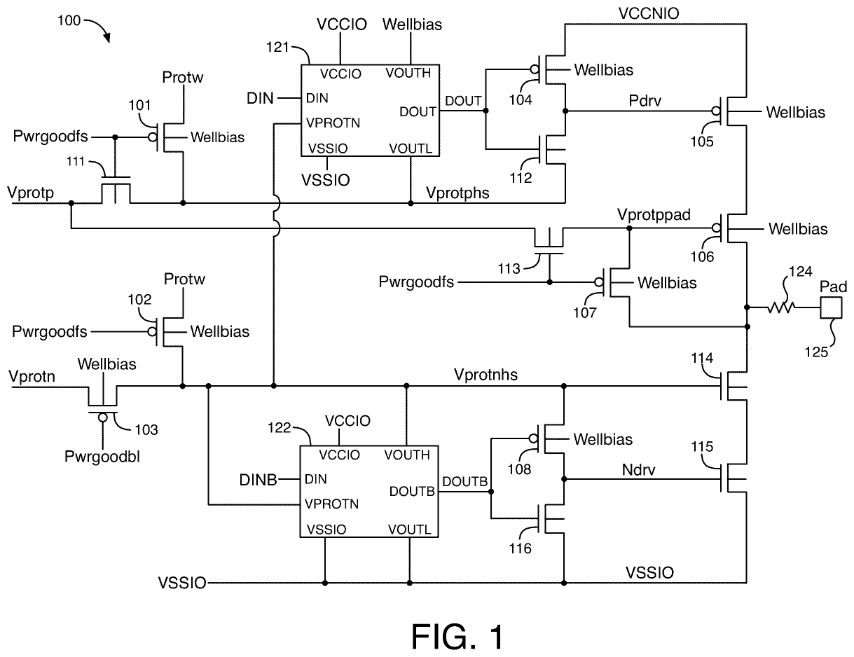

FIG. 1 is a diagram that depicts an example of an output driver circuit 100 in an integrated circuit (IC) that can support a high voltage at an external pad 125 of the IC during a hot-socket condition of the IC. The output driver circuit 100 of Figure (FIG. 1 includes 8 p-channel field-effect transistors (FETs) (e.g., p-channel metal-oxide-semiconductor field-effect transistors (MOSFETs)) 101-108, 6 n-channel FETs (e.g., N-channel MOSFETs) 111-116, and 2 level shifter circuits 121 and 122. Output driver circuit 100 is coupled to the external pad 125 of the IC through a resistor 124 in the IC (e.g., representing parasitic resistance of a conductor). External pad 125 is an external terminal of the IC. Output driver circuit 100 can be fabricated in any type of IC, such as for example, a configurable IC (e.g., an FPGA), a microprocessor IC, a graphics processing unit IC, a memory IC, an application specific IC, a transceiver IC, a memory IC, etc.

The output driver circuit 100 of FIG. 1 is configurable to operate in a data output mode of operation. During the data output mode of operation, output driver circuit 100 drives values of a differential input data signal that equals the difference between signals DIN and DINB to the external pad 125. The level shifter circuit 121 receives signal DIN, a first supply voltage VCCIO, a bias voltage Wellbias, a voltage Vprotnhs, a ground voltage VSSIO, and a voltage Vprotphs at its input terminals DIN, VCCIO, VOUTH, VPROTN, VSSIO, and VOUTL, respectively. Signal DIN varies between voltages VCCIO and VSSIO. Level shifter circuit 121 shifts the voltage range of signal DIN to generate an output signal DOUT that varies between voltages Wellbias and Vprotphs at its output DOUT. Level shifter circuit 121 causes signal DOUT to indicate the same logic values received in signal DIN during the data output mode of operation. Signal DOUT is provided to the gates of FETs 104 and 112.

The level shifter circuit 122 receives signal DINB, supply voltage VCCIO, voltage Vprotnhs, and ground voltage VSSIO at its input terminals DIN, VCCIO, VOUTH, VPROTN, VSSIO, and VOUTL, as shown in FIG. 1. Signal DINB varies between voltages VCCIO and VSSIO. Level shifter circuit 122 shifts the voltage range of signal DINB to generate an output signal DOUTB that varies between voltages Vprotnhs and VSSIO at its output DOUTB. Level shifter circuit 122 causes signal DOUTB to indicate the same logic values received in signal DINB during the data output mode of operation. Signal DOUTB is provided to the gates of FETs 108 and 116.

A power-on signal Pwrgoodfs is provided to the gates of FETs 101, 102, 107, 111, and 113. The power-on signal Pwrgoodfs varies between the Wellbias voltage and voltage VSSIO. A signal Pwrgoodbl is provided to the gate of FET 103. Signal Pwrgoodbl is the logical inverse of signal Pwrgoodfs. Signal Pwrgoodbl varies between a voltage Protw and ground voltage VSSIO. FETs 101 and 111 are a first multiplexer circuit controlled by signal Pwrgoodfs. FETs 102-103 are a second multiplexer circuit controlled by signals Pwrgoodfs and Pwrgoodbl. FETs 107 and 113 are a third multiplexer circuit controlled by signal Pwrgoodfs.

To cause output driver circuit 100 to operate in the data output mode of operation, signal Pwrgoodfs is driven to a high voltage (e.g., 3.3 volts), and signal Pwrgoodbl is driven to 0 volts. As a result, FETs 101-102 and 107 are off, and FETs 103, 111, and 113 are on. During the data output mode of operation, a voltage Vprotp is provided through FET 113 in the third multiplexer circuit to the gate of FET 106 as voltage Vprotppad and through FET 111 in the first multiplexer circuit to the VOUTL input of level shifter circuit 121 and the source of FET 112. Also, during the data output mode of operation, a voltage Vprotn is provided through FET 103 in the second multiplexer circuit to the gate of FET 114, to the source of FET 108, and to the VPROTN and VOUTH inputs of level shifter circuit 122 as voltage Vprotnhs. Voltage Vprotnhs is also provided to the VPROTN input of level shifter circuit 121.

The voltages Vprotp and Vprotn are generated internally within the IC from the supply voltage VCCIO. As examples, voltage Vprotp equals VCCIO-1.8 volts, and voltage Vprotn equals 1.8 volts. Voltage Vprotp is provided as a bias voltage for FET 106 (as voltage Vprotppad) during the data output mode of operation. In addition, voltage Vprotp functions as an elevated ground voltage for the entire p-channel FET path of output driver circuit 100 during the data output mode of operation so that the voltage across the p-channel FETs 105-106 only swings between the voltage VCCIO and voltage Vprotp levels (e.g., (VCCIO-(VCCIO-1.8 volts))=1.8 volts) and does not over stress the FETs 105-106. The voltage Vprotn (e.g., 1.8 volts) is provided to the n-channel FET 114 as the n-channel FET stack bias voltage Vprotnhs and as the supply rail voltage for the n-channel FET path during the data output mode of operation. As a result, when a second supply voltage VCCNIO is 3.3 volts, none of the p-channel FETs 105-106 nor the n-channel FETs 114-115 become over stressed (e.g., experience a voltage drop greater than 1.8 volts).

During the data output mode of operation, the level shifter circuits 121-122 shift the voltage ranges of signals DIN and DINB to generate output signals DOUT and DOUTB, respectively. A pre-driver circuit that includes the FETs 104 and 112 drives the inverse value of signal DOUT to the gate of FET 105 as signal Pdrv, and a pre-driver circuit that includes the FETs 108 and 116 drives the inverse value of signal DOUTB to the gate of FET 115 as signal Ndrv. FETs 106 and 114 are enabled (i.e., turned on) in response to the voltages Vprotppad and Vprotnhs, respectively, in the data output mode of operation. As a result, the pre-driver circuits and the FETs 105-106 and 114-115 drive the values of the differential data signal that equals DIN-DINB to pad 125 through resistor 124 as an output signal of the IC during the data output mode of operation.

Each of the FETs 101-108 and 111-116 in output driver circuit 100 can support a voltage up to 1.8 volts without breakdown. P-channel FETs 105 and 106 are coupled in a stacked configuration between the resistor 124 and a supply terminal at the second supply voltage VCCNIO. N-channel FETs 114 and 115 are coupled in a stacked configuration between the resistor 124 and a ground terminal at ground voltage VSSIO. The stacked configurations of the FETs 105-106 and 114-115 allow these FETs to support a high voltage up to 3.3 volts at pad 125 during hot-socket conditions of the IC without experiencing breakdown.

The bias voltage Wellbias is also provided to the body terminal of each of the p-channel FETs 101-108 in output driver circuit 100. Each of the p-channel FETs 101-108 can, as examples, be formed in an n-type well or n-type substrate. The bias voltage Wellbias prevents the body diodes of the p-channel FETs 101-108 from becoming forward biased during hot-socket conditions at pad 125. The body terminals of the n-channel FETs 111-116 in output driver circuit 100 are coupled to ground voltage VSSIO.

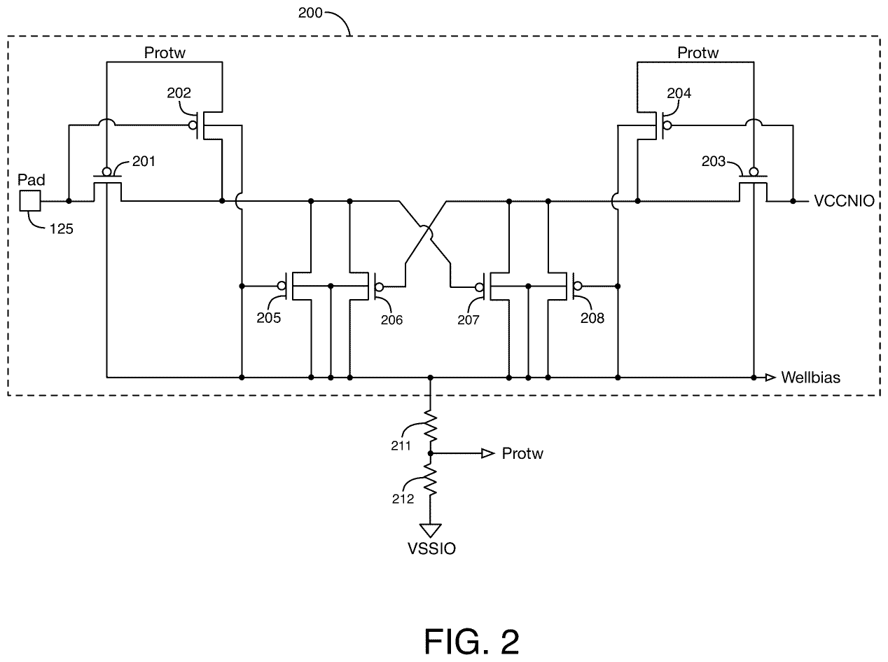

FIG. 2 is a diagram that illustrates an example of a clamp protection circuit 200 in the IC that generates the bias voltage Wellbias in response to the voltage at pad 125 and the supply voltage VCCNIO shown in FIG. 1. The bias voltage Wellbias generated by clamp protection circuit 200 is provided to the body terminals of p-channel FETs 101-108 and to level shifter circuit 121 in output driver circuit 100, as discussed above.

The clamp protection circuit 200 includes 8 p-channel field-effect transistors (FETs) 201-208 (e.g., p-MOSFETs). The clamp protection circuit 200 is coupled to 2 resistors 211-212. The bias voltage Wellbias is also provided to the body terminals of FETs 201-208. The pad 125 is coupled to the gate of FET 202 and to the source/drain of FET 201, and the supply voltage VCCNIO is provided to the gate of FET 204 and to the source/drain of FET 203.

The clamp protection circuit 200 provides the input voltage that is greater (either the voltage at pad 125 or voltage VCCNIO) to the bias voltage Wellbias. Thus, if the voltage at pad 125 is greater than supply voltage VCCNIO (e.g., during a hot socket condition), FETs 201 and 205-206 are on, pulling the bias voltage Wellbias to the voltage at the pad 125, and FETs 207-208 are off. If supply voltage VCCNIO is greater than the voltage at pad 125 (e.g., during the data output mode of operation), FETs 203 and 207-208 are on, pulling the bias voltage Wellbias to the supply voltage VCCNIO, and FETs 205-206 are off.

Resistors 211 and 212 are a resistor divider that receives bias voltage Wellbias and that generates an output voltage Protw that is a fraction of Wellbias. According to an example used herein, resistors 211 and 212 have the same resistance, and as a result, resistors 211-212 cause voltage Protw to equal one-half of bias voltage Wellbias (i.e., Protw=Wellbias/2). The voltage Protw is provided to the gates of FETs 201 and 203 and to the sources of FETs 202 and 204, as shown in FIG. 2.

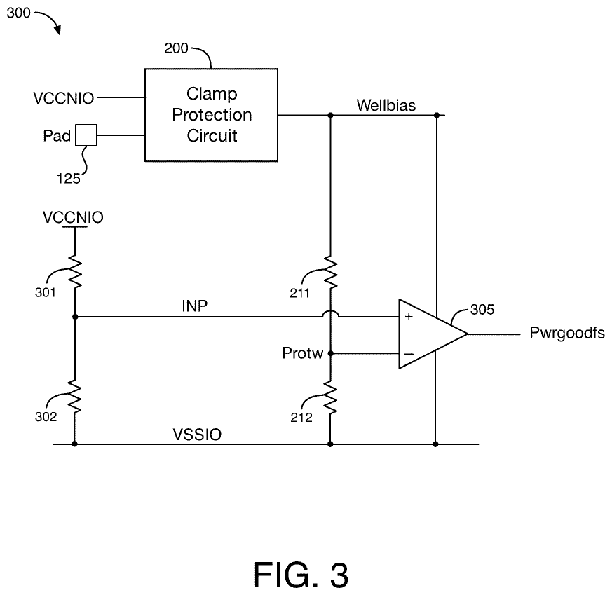

FIG. 3 is a diagram that illustrates an example of a power detector circuit 300 in the IC. The power detector circuit 300 includes the clamp protection circuit 200 disclosed herein with respect to FIG. 2, 4 resistors 211-212 and 301-302, and a comparator circuit 305. Clamp protection circuit 200 operates as disclosed herein with respect to FIG. 2 in response to voltage VCCNIO and the voltage at pad 125. Resistors 211-212 are coupled in series between the node at bias voltage Wellbias at the output of clamp protection circuit 200 and a ground terminal at ground voltage VSSIO. Resistors 301 and 302 are coupled in series between the supply terminal at supply voltage VCCNIO and the ground terminal at ground voltage VSSIO.

As discussed above, resistors 211-212 are a resistor divider that generates a voltage Protw that equals one-half of the bias voltage Wellbias (i.e., Protw=0.5*Wellbias). The voltage Protw is provided to the inverting input of the comparator circuit 305. Resistors 301-302 are a second resistor divider that generates a voltage INP between resistors 301 and 302. Resistors 301-302 have resistances that cause voltage INP to equal 0.56 times VCCNIO-VSSIO (i.e., INP=0.56*(VCCNIO-VSSIO)). Voltage INP is provided to the non-inverting input of the comparator circuit 305.

Comparator circuit 305 compares voltage INP to voltage Protw to generate the voltage of signal Pwrgoodfs at its output terminal. Comparator circuit 305 receives voltages Wellbias and VSSIO as high and low supply voltages. During the data output mode of operation, the supply voltage VCCNIO is greater than the voltage at pad 125, clamp protection circuit 200 causes bias voltage Wellbias to equal voltage VCCNIO as discussed above, and as a result, voltage INP is greater than voltage Protw. When voltage INP is greater than voltage Protw, comparator circuit 305 causes the voltage of signal Pwrgoodfs to be high (i.e., at bias voltage Wellbias), and the voltage of signal Pwrgoodbl to be at 0 volts (e.g., using an inverter).

During a hot-socket condition at pad 125, the voltage at pad 125 is greater than supply voltage VCCNIO, clamp protection circuit 200 causes bias voltage Wellbias to equal the voltage at pad 125 as discussed above, and as a result, voltage INP is less than voltage Protw. When voltage INP is less than voltage Protw, comparator circuit 305 causes the voltage of signal Pwrgoodfs to be low (i.e., at voltage VSSIO) and the voltage of signal Pwrgoodbl to increase to a higher voltage (e.g., about 1.7 volts).

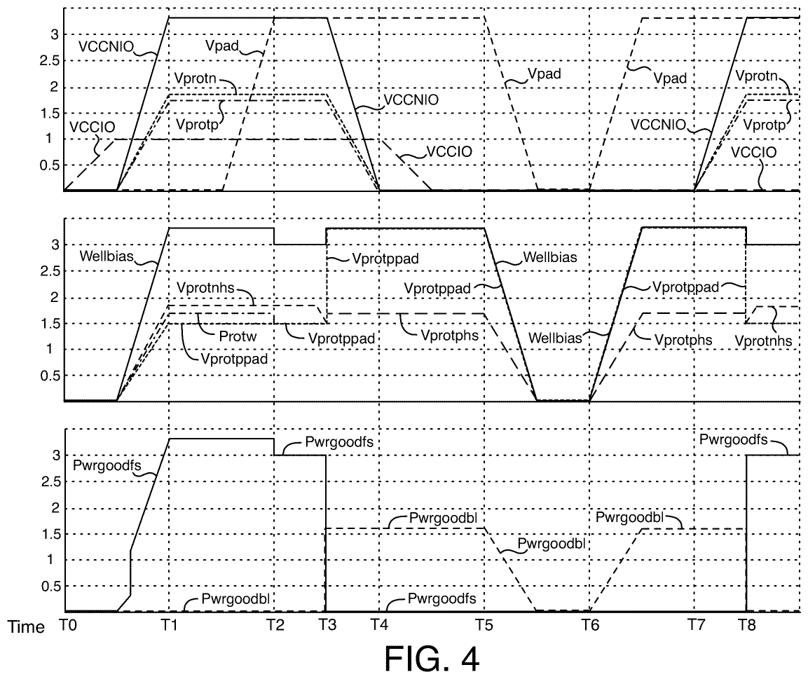

FIG. 4 depicts timing diagrams that illustrate examples of voltage waveforms in the output driver circuit 100, the clamp protection circuit 200, and the power detector circuit 300 during the data output mode of operation and during a hot-socket protection mode of operation. The upper diagram of Figure (FIG. 4 illustrates examples of voltage waveforms for voltage VCCNIO, the voltage Vpad at pad 125, Vprotn, Vprotp, and voltage VCCIO. The middle diagram of FIG. 4 illustrates examples of voltage waveforms for Wellbias, Vprotnhs, Protw, Vprotphs, and Vprotppad. The lower diagram of FIG. 4 illustrates examples of voltage waveforms for signals Pwrgoodfs and Pwrgoodbl.

Between times T0 and T1 shown in FIG. 4, supply voltage VCCNIO increases to 3.3 volts, supply voltage VCCIO increases to about 1 volt, the voltage Vprotp increases to about 1.7 volts, the voltage Vprotn increases to about 1.8 volts, the voltage Vpad at pad 125 is at 0 volts, the bias voltage Wellbias increases to 3.3 volts, voltage Vprotnhs increases to about 1.8 volts, voltage Protw increases to about 1.7 volts, and voltage Vprotppad increases to about 1.5 volts. Between times T1 and T3 shown in FIG. 4, the output driver circuit 100 operates in the data output mode of operation. During the data output mode of operation of output driver circuit 100, level shifter circuits 121-122, the pre-driver circuits, and the FETs 105-106 and 114-115 drive the values of the differential input data signal that equals DIN-DINB to pad 125 through resistor 124 as an output signal of the IC, as described in detail above.

The voltage Vpad at pad 125 increases from 0 volts to 3.3 volts between times T1 and T2 shown in FIG. 4. When the IC that includes output driver circuit 100 is un-powered, voltages VCCNIO, Vprotn, and Vprotp decrease to 0 volts between times T3 and T4, and supply voltage VCCIO decreases to 0 volts after time T4, as shown in FIG. 4. When the IC is un-powered after time T4, the output driver circuit 100 supports the hot-socket protection mode of operation. When a voltage of 3.3 volts is driven to pad 125 and the IC is un-powered, the output driver circuit 100 provides hot-socket protection to the FETs 105-106 and 114-115 in the hot-socket protection mode of operation by preventing a voltage greater than 1.8 volts from being applied across any of the FETs 105-106 and 114-115 so that these FETs do not become over stressed and breakdown.

During the hot-socket protection mode of operation, clamp protection circuit 200 provides the voltage Vpad of pad 125 to the Wellbias voltage, because Vpad is greater than voltage VCCNIO after time T3. As shown in FIG. 4, the Wellbias voltage is at 3.3 volts between times T3 and T5. Thus, the voltage Vpad from pad 125 is used to bias the body terminals of the p-channel FETs in output driver circuit 100 via voltage Wellbias during the hot-socket protection mode of operation. As a result, during the hot-socket protection mode of operation, the Wellbias voltage prevents the body diodes of the p-channel FETs in output driver circuit 100 from being forward biased, thus preventing large current flows through the p-channel FET body diodes to pad 125.

In response to the supply voltage VCCNIO decreasing below 3.3 volts after time T3, comparator circuit 305 causes the voltage of signal Pwrgoodfs to decrease to zero volts and the voltage of signal Pwrgoodbl to increase to about 1.7 volts at time T3, as shown in FIG. 4. In response to the voltage of signal Pwrgoodfs decreasing to zero volts, FETs 101-102 and 107 turn on, and FETs 111 and 113 turn off. In response to the voltage of signal Pwrgoodbl increasing to about 1.7 volts, FET 103 turns off. As a result, the output driver circuit 100 functions in the hot-socket protection mode of operation.

In the hot-socket protection mode of operation, signal Pwrgoodfs turns FET 107 on and turns FET 113 off in the third multiplexer circuit to couple pad 125 to the gate (i.e., the control input) of FET 106 through resistor 124 and FET 107 and to decouple FET 106 from the node at voltage Vprotp. As a result, the voltage Vprotppad increases from about 1.5 volts to 3.3 voltages at time T3, as shown in FIG. 4, to approximately equal the voltage Vpad at the pad 125. Thus, the voltage Vpad at pad 125 drives the voltage at the gate of FET 106 during the hot-socket protection mode of operation to prevent breakdown of FET 106.

In the hot-socket protection mode of operation, signal Pwrgoodfs turns FET 101 on and FET 111 off in the first multiplexer circuit to couple the source of FET 112 at voltage Vprotphs to the node at voltage Protw through FET 101. Signal Pwrgoodfs turns FET 102 on and signal Pwrgoodbl turns FET 103 off in the second multiplexer circuit to couple the source of FET 108 and the gate (i.e., the control input) of FET 114 at voltage Vprotnhs to the node at voltage Protw through FET 102. As a result, the gate of FET 114 and the source of FET 108 are coupled to pad 125 through FET 102, resistor 211, FETs 205-206, and FET 201 in the hot-socket protection mode of operation, because voltage Vpad is greater than voltage VCCNIO. Thus, the voltage Vpad at pad 125 drives the voltage at the gate of FET 114 through clamp protection circuit 200 and FET 102 during the hot-socket protection mode of operation to prevent breakdown of FET 114.

Between times T4 and T5 shown in FIG. 4, the voltage Vprotphs is about 1.7 volts, the voltage Pdrv is about 1.5 volts, and the voltage Ndrv is 0 volts. As a result, no more than 1.8 volts is applied across each one of the stacked FETs 105, 106, 114, and 115. Therefore, none of the FETs 105, 106, 114, and 115 become over stressed or experience breakdown during the hot-socket condition in the hot-socket protection mode of operation.

After time T5, the pad voltage Vpad, voltage Vprotppad, and the Wellbias voltage decrease to zero volts as shown in FIG. 4. After time T6, the pad voltage Vpad, voltage Vprotppad, and the Wellbias voltage increase back to 3.3 volts, as shown in FIG. 4. After time T7, supply voltage VCCNIO increases back to 3.3 volts, the voltage Vprotp increases to about 1.7 volts, and the voltage Vprotn increases to about 1.8 volts. At time T8, the comparator circuit 305 causes the voltage of signal Pwrgoodfs to increase to 3 volts and the voltage of signal Pwrgoodbl to decrease to 0 volts, and the output driver circuit 100 returns to the data output mode of operation.

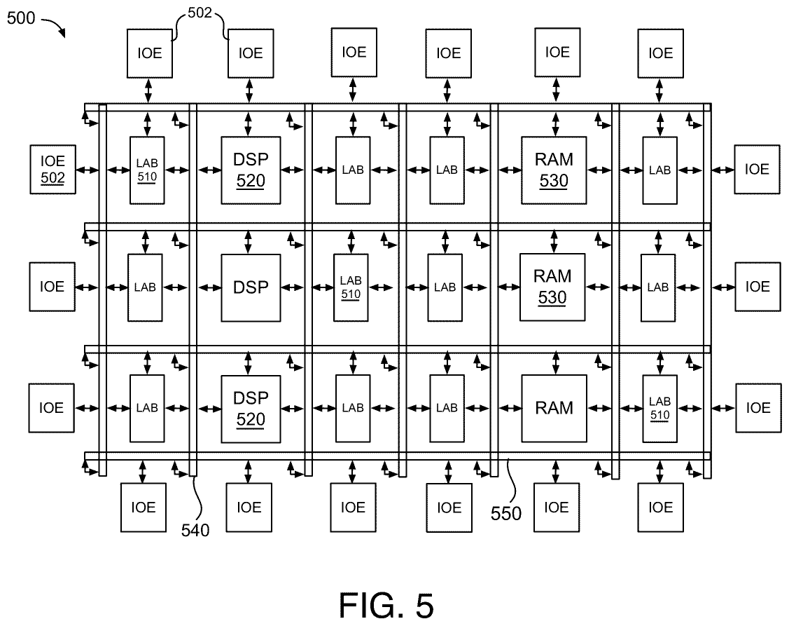

FIG. 5 is a diagram that illustrates an example of a configurable logic integrated circuit (IC) 500 that can include any of the circuitry disclosed herein with respect to FIGS. 1-3. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, configurable logic IC 500 can have input/output elements (IOEs) 502 for driving signals off of configurable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the configurable logic IC 500 can have input/output elements 502 arranged in different ways. For example, input/output elements 502 can form one or more columns, rows, or islands of input/output elements that may be located anywhere on configurable logic IC 500.

The configurable logic IC 500 can also include programmable interconnect circuitry in the form of vertical routing channels 540 (i.e., interconnects formed along a vertical axis of configurable logic IC 500) and horizontal routing channels 550 (i.e., interconnects formed along a horizontal axis of configurable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Configurable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, configurable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

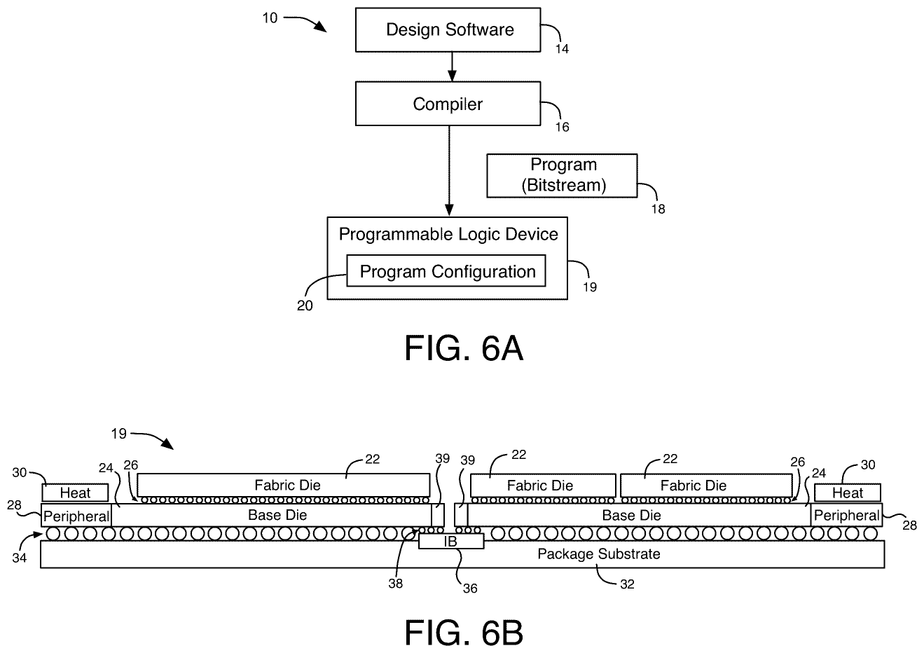

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

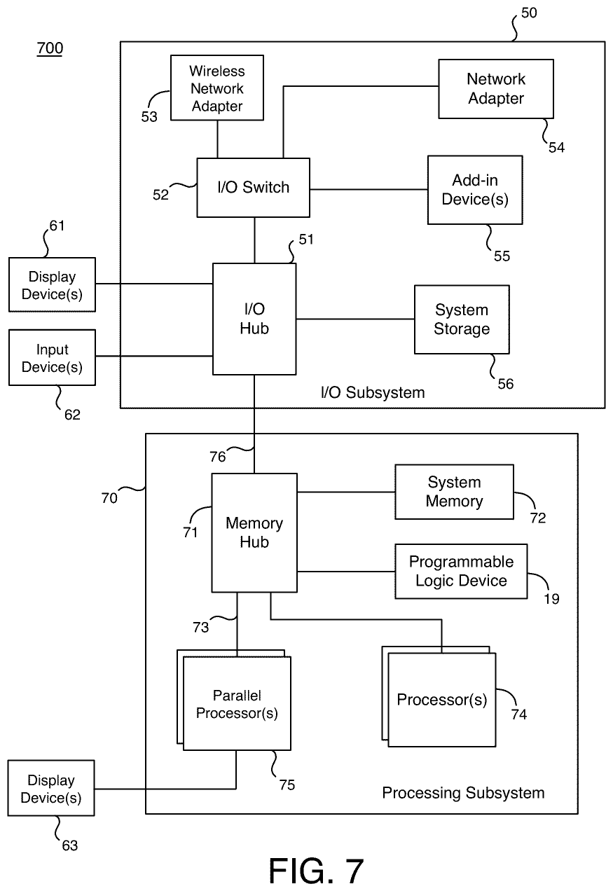

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising: an output driver circuit that comprises first and second multiplexer circuits and first and second transistors coupled to an external pad of the integrated circuit, wherein the first multiplexer circuit is configurable to cause the first transistor to be controlled by a first voltage during a data output mode of operation and to couple a first control input of the first transistor to the external pad during a hot-socket protection mode of operation, and wherein the second multiplexer circuit is configurable to cause the second transistor to be controlled by a second voltage during the data output mode of operation and to couple a second control input of the second transistor to the external pad during the hot-socket protection mode of operation.

In Example 2, the integrated circuit of Example 1 further comprises: a clamp protection circuit that couples the external pad to the second control input of the second transistor through the second multiplexer circuit during the hot-socket protection mode of operation in response to a third voltage at the external pad being greater than a supply voltage.

In Example 3, the integrated circuit of Example 2 can optionally include, wherein the clamp protection circuit couples a body terminal of the first transistor to a node at the supply voltage in response to the supply voltage being greater than the third voltage.

In Example 4, the integrated circuit of any one of Examples 1-3 can optionally include, wherein the output driver circuit further comprises a third multiplexer circuit that is configurable to provide the first voltage to a pre-driver circuit during the data output mode of operation and to couple the pre-driver circuit to the external pad during the hot-socket protection mode of operation.

In Example 5, the integrated circuit of any one of Examples 1˜4 further comprises: a clamp protection circuit that generates an output voltage based on a greater of a fourth voltage at the external pad or a supply voltage provided to the output driver circuit; and a comparator circuit that generates a control signal that controls the first and the second multiplexer circuits by comparing the output voltage to a sixth voltage generated based on the supply voltage.

In Example 6, the integrated circuit of any one of Examples 1-5 can optionally include, wherein the output driver circuit further comprises a third transistor coupled between the first transistor and a supply voltage node and a fourth transistor coupled between the second transistor and a ground node.

In Example 7, the integrated circuit of any one of Examples 1-6 can optionally include, wherein the output driver circuit further comprises a first pre-driver circuit and a third transistor coupled between the first transistor and a supply voltage node, and wherein the first pre-driver circuit is configurable to drive a first output signal to the external pad using the first and the third transistors during the data output mode of operation.

In Example 8, the integrated circuit of Example 7 can optionally include, wherein the output driver circuit further comprises a second pre-driver circuit and a fourth transistor coupled between the second transistor and a ground voltage node, and wherein the second pre-driver circuit is configurable to drive a second output signal to the external pad using the second and the fourth transistors during the data output mode of operation.

In Example 9, the integrated circuit of any one of Examples 1-8 can optionally include, wherein the first multiplexer circuit comprises a third transistor coupled between the first control input of the first transistor and the external pad, and wherein the first multiplexer circuit further comprises a fourth transistor coupled between the first control input of the first transistor and a node at the first voltage.

In Example 10, the integrated circuit of any one of Examples 1-9 can optionally include, wherein the second multiplexer circuit comprises a third transistor coupled between the second control input of the second transistor and a clamp protection circuit that is coupled to the external pad, and wherein the second multiplexer circuit further comprises a fourth transistor coupled between the second control input of the second transistor and a node at the second voltage.

Example 11 is a method for protecting an integrated circuit during a hot-socket condition, the method comprising: configuring a first multiplexer circuit to cause a first transistor in an output driver circuit to be controlled by a first voltage; configuring a second multiplexer circuit to cause a second transistor in the output driver circuit to be controlled by a second voltage, wherein the integrated circuit comprises the output driver circuit; driving an output signal to an external terminal of the integrated circuit using the first and the second transistors in response to the first and the second voltages; and configuring the first and the second multiplexer circuits to couple a first control input of the first transistor and a second control input of the second transistor to the external terminal during the hot-socket condition.

In Example 12, the method of Example 11 further comprises: configuring a third multiplexer circuit to provide the first voltage to a pre-driver circuit while the output driver circuit drives the output signal to the external terminal; and configuring the third multiplexer circuit to couple the pre-driver circuit to the external terminal during the hot-socket condition.

In Example 13, the method of any one of Examples 11-12 further comprises: coupling the external terminal to the second control input of the second transistor through a clamp protection circuit and through the second multiplexer circuit during the hot-socket condition in response to a third voltage at the external terminal being greater than a supply voltage provided to the clamp protection circuit.

In Example 14, the method of any one of Examples 11-13 further comprises: coupling a body terminal of the first transistor to a node at a supply voltage through a clamp protection circuit in response to the supply voltage being greater than a third voltage at the external terminal.

In Example 15, the method of any one of Examples 11-14 further comprises: generating an output voltage based on a greater of a fourth voltage at the external terminal or a supply voltage received at the output driver circuit using a clamp protection circuit; and comparing the output voltage to a sixth voltage generated based on the supply voltage using a comparator circuit to generate a control signal that controls the first and the second multiplexer circuits.

In Example 16, the method of any one of Examples 11-15 can optionally include, wherein driving the output signal to the external terminal using the first and the second transistors further comprises driving a first data signal to the external terminal using a third transistor coupled between the first transistor and a supply voltage node, and driving a second data signal to the external terminal using a fourth transistor coupled between the second transistor and a ground node.

Example 17 is an integrated circuit comprising: an output driver circuit comprising first and second transistors coupled to an external pad, wherein the output driver circuit further comprises first and second multiplexer circuits that are configurable to enable the first and the second transistors to allow the output driver circuit to drive an output signal to the external pad, and wherein the first multiplexer circuit is configurable to couple a first control input of the first transistor to the external pad during a hot-socket condition; and a clamp protection circuit that couples the external pad to a second control input of the second transistor through the second multiplexer circuit during the hot-socket condition in response to a first voltage at the external pad being greater than a supply voltage at a supply terminal.

In Example 18, the integrated circuit of Example 17 can optionally include, wherein the second multiplexer circuit is configurable to couple the second control input of the second transistor to the clamp protection circuit during the hot-socket condition in response to the first voltage at the external pad being greater than the supply voltage.

In Example 19, the integrated circuit of any one of Examples 17-18 further comprises: a comparator circuit that controls the first and the second multiplexer circuits by comparing a third voltage generated based on an output voltage of the clamp protection circuit to a fifth voltage generated based on the supply voltage.

In Example 20, the integrated circuit of any one of Examples 17-19 can optionally include, wherein the output driver circuit further comprises a third transistor coupled between the first transistor and the supply terminal and a fourth transistor coupled between the second transistor and a ground terminal, and wherein the output driver circuit drives the output signal to the external pad through the first, the second, the third, and the fourth transistors.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
an output driver circuit that comprises first and second multiplexer circuits and first and second transistors coupled to an external pad of the integrated circuit,
wherein the first multiplexer circuit is configurable to cause the first transistor to be controlled by a first voltage during a data output mode of operation and to couple a first control input of the first transistor to the external pad during a hot-socket protection mode of operation, and wherein the second multiplexer circuit is configurable to cause the second transistor to be controlled by a second voltage during the data output mode of operation and to couple a second control input of the second transistor to the external pad during the hot-socket protection mode of operation.

2. The integrated circuit of claim 1 further comprising:
a clamp protection circuit that couples the external pad to the second control input of the second transistor through the second multiplexer circuit during the hot-socket protection mode of operation in response to a third voltage at the external pad being greater than a supply voltage.

3. The integrated circuit of claim 2, wherein the clamp protection circuit couples a body terminal of the first transistor to a node at the supply voltage in response to the supply voltage being greater than the third voltage.

4. The integrated circuit of claim 1, wherein the output driver circuit further comprises a third multiplexer circuit that is configurable to provide the first voltage to a pre-driver circuit during the data output mode of operation and to couple the pre-driver circuit to the external pad during the hot-socket protection mode of operation.

5. The integrated circuit of claim 1 further comprising:
a clamp protection circuit that generates an output voltage based on a greater of a fourth voltage at the external pad or a supply voltage provided to the output driver circuit; and
a comparator circuit that generates a control signal that controls the first and the second multiplexer circuits by comparing the output voltage to a sixth voltage generated based on the supply voltage.

6. The integrated circuit of claim 1, wherein the output driver circuit further comprises a third transistor coupled between the first transistor and a supply voltage node and a fourth transistor coupled between the second transistor and a ground node.

7. The integrated circuit of claim 1, wherein the output driver circuit further comprises a first pre-driver circuit and a third transistor coupled between the first transistor and a supply voltage node, and wherein the first pre-driver circuit is configurable to drive a first output signal to the external pad using the first and the third transistors during the data output mode of operation.

8. The integrated circuit of claim 7, wherein the output driver circuit further comprises a second pre-driver circuit and a fourth transistor coupled between the second transistor and a ground voltage node, and wherein the second pre-driver circuit is configurable to drive a second output signal to the external pad using the second and the fourth transistors during the data output mode of operation.

9. The integrated circuit of claim 1, wherein the first multiplexer circuit comprises a third transistor coupled between the first control input of the first transistor and the external pad, and wherein the first multiplexer circuit further comprises a fourth transistor coupled between the first control input of the first transistor and a node at the first voltage.

10. The integrated circuit of claim 1, wherein the second multiplexer circuit comprises a third transistor coupled between the second control input of the second transistor and a clamp protection circuit that is coupled to the external pad, and wherein the second multiplexer circuit further comprises a fourth transistor coupled between the second control input of the second transistor and a node at the second voltage.

11. A method for protecting an integrated circuit during a hot-socket condition, the method comprising:
configuring a first multiplexer circuit to cause a first transistor in an output driver circuit to be controlled by a first voltage;
configuring a second multiplexer circuit to cause a second transistor in the output driver circuit to be controlled by a second voltage, wherein the integrated circuit comprises the output driver circuit;
driving an output signal to an external terminal of the integrated circuit using the first and the second transistors in response to the first and the second voltages; and
configuring the first and the second multiplexer circuits to couple a first control input of the first transistor and a second control input of the second transistor to the external terminal during the hot-socket condition.

12. The method of claim 11 further comprising:
configuring a third multiplexer circuit to provide the first voltage to a pre-driver circuit while the output driver circuit drives the output signal to the external terminal; and
configuring the third multiplexer circuit to couple the pre-driver circuit to the external terminal during the hot-socket condition.

13. The method of claim 11 further comprising:
coupling the external terminal to the second control input of the second transistor through a clamp protection circuit and through the second multiplexer circuit during the hot-socket condition in response to a third voltage at the external terminal being greater than a supply voltage provided to the clamp protection circuit.

14. The method of claim 11 further comprising:
coupling a body terminal of the first transistor to a node at a supply voltage through a clamp protection circuit in response to the supply voltage being greater than a third voltage at the external terminal.

15. The method of claim 11 further comprising:
generating an output voltage based on a greater of a fourth voltage at the external terminal or a supply voltage received at the output driver circuit using a clamp protection circuit; and
comparing the output voltage to a sixth voltage generated based on the supply voltage using a comparator circuit to generate a control signal that controls the first and the second multiplexer circuits.

16. The method of claim 11, wherein driving the output signal to the external terminal using the first and the second transistors further comprises driving a first data signal to the external terminal using a third transistor coupled between the first transistor and a supply voltage node, and driving a second data signal to the external terminal using a fourth transistor coupled between the second transistor and a ground node.

17. An integrated circuit comprising:
an output driver circuit comprising first and second transistors coupled to an external pad, wherein the output driver circuit further comprises first and second multiplexer circuits that are configurable to enable the first and the second transistors to allow the output driver circuit to drive an output signal to the external pad, and wherein the first multiplexer circuit is configurable to couple a first control input of the first transistor to the external pad during a hot-socket condition; and
a clamp protection circuit that couples the external pad to a second control input of the second transistor through the second multiplexer circuit during the hot-socket condition in response to a first voltage at the external pad being greater than a supply voltage at a supply terminal.

18. The integrated circuit of claim 17, wherein the second multiplexer circuit is configurable to couple the second control input of the second transistor to the clamp protection circuit during the hot-socket condition in response to the first voltage at the external pad being greater than the supply voltage.

19. The integrated circuit of claim 17 further comprising:
a comparator circuit that controls the first and the second multiplexer circuits by comparing a third voltage generated based on an output voltage of the clamp protection circuit to a fifth voltage generated based on the supply voltage.

20. The integrated circuit of claim 17, wherein the output driver circuit further comprises a third transistor coupled between the first transistor and the supply terminal and a fourth transistor coupled between the second transistor and a ground terminal, and wherein the output driver circuit drives the output signal to the external pad through the first, the second, the third, and the fourth transistors.
